(19) United States
(12) Patent Application Publication
(10) Pub. No.: US 2016/0284894 A1
(43) Pub. Date: Sep. 29, 2016

(54) Method for Producing a Solar Cell and the Solar Cell

(71) Applicant: SHARP KABUSHIKI KAISHA, OSAKA (JP)

(72) Inventors: Satoshi TANAKA, Osaka (JP); Yoshihiro OHISHI, Osaka (JP)

(21) Appl. No.: 15/178,939

(22) Filed: Jun. 10, 2016

Related U.S. Application Data
(63) Continuation of application No. 14/371,378, filed on Jul. 9, 2014.

(30) Foreign Application Priority Data
Jan. 10, 2012 (JP) 2012-001913

(51) Int. Cl. H01L 31/0224; H01L 31/0216

(52) U.S. Cl. CPC H01L 31/022433; H01L 31/02168; H01L 31/0224

(57) ABSTRACT

A solar cell, which comprises a substrate, a sub grid electrode and a main grid electrode directly contacting the substrate, wherein the main grid electrode and the sub grid electrode comprise silver particles, and wherein a particle size of the silver particles comprised in the main grid electrode is smaller than a particle size of the silver particles comprised in the sub grid electrode, is provided.

This application is a continuation of U.S. patent application Ser. No. 14/371,378 filed 9 Jul. 2014 (pending) which is the U.S. national phase of International Application No. PCT/JP2012/083805 filed 27 Dec. 2012 which designated the U.S. and claims priority to JP Patent Application No. 2012-001913 filed 10 Jan. 2012, the entire contents of each of which are hereby incorporated by reference.

### TECHNICAL FIELD

The present invention relates to a method for producing a solar cell, and the solar cell.

### BACKGROUND ART

In recent years, solar cells that convert solar energy directly into electrical energy are increasingly, rapidly expected as an energy source for the next generation in view of global environmental issues in particular. While there is a variety of solar cells such as those using compound semiconductor, organic material and/or the like, those using silicon crystal are currently mainstream.

A type of solar cell currently most produced and sold has a structure with a light-receiving surface and a surface opposite to the light-receiving surface (i.e., a back surface) provided with electrodes, respectively.

FIG. 6 shows a schematic plan view of a light receiving surface of a solar cell disclosed in Japanese Patent Laying-Open No. 2004-014566 (PTD 1), and FIG. 7 shows a schematic cross section along a line VII-VII shown in FIG. 6.

As shown in FIG. 7, a solar cell 101 disclosed in PTD 1 has an n type impurity diffusion layer 104 formed on a surface of a p type silicon substrate 103 as a base member closer to a light receiving surface 121 of solar cell 101. Furthermore, an anti-reflection film 105 is formed to cover n type impurity diffusion layer 104.

Furthermore, as shown in FIG. 6 and FIG. 7, on light receiving surface 121, an electrode unit 102 by a silver electrode is formed. Electrode unit 102 is configured of a main grid 102a and a sub grid 102b.

Furthermore, as shown in FIG. 7, on a back surface 122 opposite to light receiving surface 121 of solar cell 101, a back surface field (BSF) layer 106 that is a p+ type layer is formed. Furthermore, on back surface 122, an aluminum electrode 107 is formed to cover BSF layer 106 and a silver electrode 108 is formed to partially overlap aluminum electrode 107.

Electrode unit 102 on light receiving surface 121 of solar cell 101 is formed by printing a silver paste by a screen printing method, and drying it, and then firing it in an oxidizing atmosphere. In firing the silver paste, electrode unit 102 penetrates anti-reflection film 105 by fire-through and is brought into contact with n type diffusion layer 104. Furthermore, in the screen printing method for the silver paste, the patterns of main grid 102a and sub grid 102b are formed in a single step using the same silver paste.

### CITATION LIST

### Patent Document

PTD 1: Japanese Patent Laying-Open No. 2004-014566

### SUMMARY

### Technical Problem

As solar energy power generation systems are rapidly widespread, it is essential to produce solar cells inexpensively. An effective means to inexpensively produce solar cells is to reduce an amount of silver used in electrode unit 102.

Reducing the amount of silver used in electrode unit 102, however, is likely to significantly impair performance of a solar cell due to an increase of resistance of electrode unit 102.

In view of the above circumstances, an object of the present invention is to provide a method for producing a solar cell and the solar cell in which an amount of silver used in an electrode can be reduced without substantially impairing performance of the solar cell.

### Solution to Problem

The present invention provides a method for producing a solar cell, including the step of forming a main grid electrode and a sub grid electrode on a surface of a substrate, a silver content in a silver paste used to form the main grid electrode being lower than a silver content in a silver paste used to form the sub grid electrode.

In the present method for producing a solar cell, preferably, a glass frit content in the silver paste used to form the main grid electrode is higher than a glass frit content in the silver paste used to form the sub grid electrode.

Furthermore, in the present method for producing a solar cell, preferably, a ratio of the glass frit content to the silver content in the silver paste used to form the main grid electrode is higher than a ratio of the glass frit content to the silver content in the silver paste used to form the sub grid electrode.

Furthermore, in the present method for producing a solar cell, preferably, a softening point of a glass frit in the silver paste used to form the main grid electrode is lower than a softening point of a glass frit in the silver paste used to form the sub grid electrode.

Furthermore, in the present method for producing a solar cell, preferably, a BET value of silver in the silver paste used to form the main grid electrode is larger than a BET value of silver in the silver paste used to form the sub grid electrode.

Furthermore, in the present method for producing a solar cell, preferably, a thickness in a center portion of the main grid electrode is thinner than a thickness in a center portion of the sub grid electrode.

Furthermore, the present invention provides a solar cell including the main grid electrode and the sub grid electrode on a surface of a substrate, the silver content in the main grid electrode being lower than the silver content in the sub grid electrode.

### Advantageous Effect

The present invention can thus provide a method for producing a solar cell and the solar cell in which an amount of silver used in an electrode can be reduced without substantially impairing performance of the solar cell.

### BRIEF DESCRIPTION OF DRAWINGS

FIG. 1 is a schematic plan view of a light receiving surface of an example of a solar cell of the present invention.

FIG. 2 is a schematic perspective view of a portion surrounded by a circle shown in FIG. 1.

FIG. 3 is a schematic plan view of joining parts of a main grid electrode and a sub grid electrode.

FIG. 4(a) is a schematic front view of a state of two solar cells connected in series, and FIG. 4(b) is a schematic side view of the state shown in FIG. 4(a).

FIG. 5(a) is a schematic front view of joining parts of a main grid electrode and a sub grid electrode, FIG. 5(b) is a schematic cross section along a line Vb-Vb shown in FIG. 5(a), and FIG. 5(c) is a schematic conceptual view for illustrating a condition of silver powders at a portion surrounded by a circle shown in FIG. 5(b).

FIG. 6 is a schematic plan view of a light receiving surface of a solar cell disclosed in PTD 1.

FIG. 7 is a schematic cross section along a line VII-VII shown in FIG. 6.

### DESCRIPTION OF EMBODIMENTS

An embodiment of the present invention will be described hereinafter. In the drawings of the present invention, the same or corresponding elements have the same reference characters allotted.

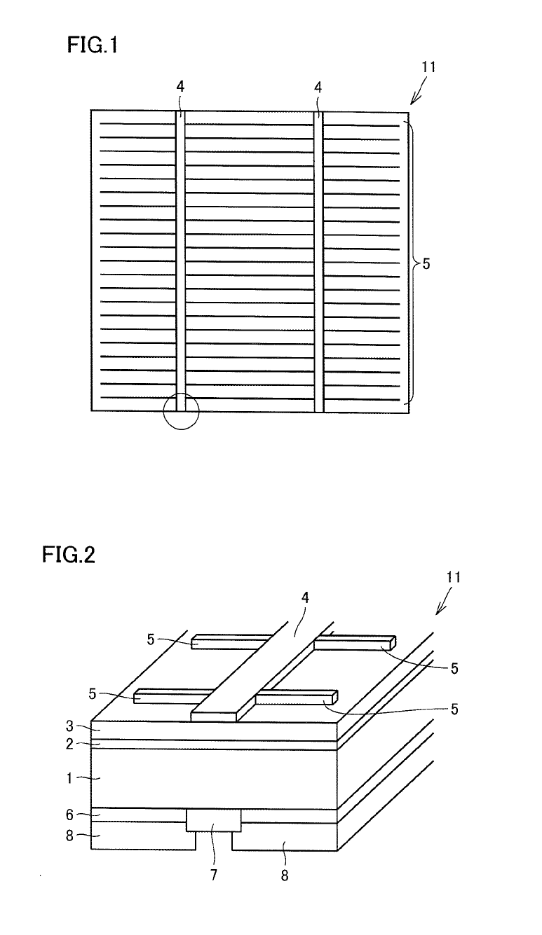

FIG. 1 shows a schematic plan view of a light receiving surface of an example of a solar cell of the present invention, and FIG. 2 shows a schematic perspective view of a portion surrounded by a circle shown in FIG. 1. A solar cell 11 shown in FIGS. 1 and 2 can be produced for example as follows:

Initially, a p type single crystal Si substrate 1 is etched and thus textured. Subsequently, a phosphoric titanate glass (PTG) liquid containing isopropoxy titanate with a phosphorus compound contained therein is applied on a light receiving surface (front surface) of p type single crystal Si substrate 1 and subsequently dried.

Subsequently, p type single crystal Si substrate 1 having the PTG liquid applied thereto and then dried is heated for example to 800° C. to 900° C. to diffuse phosphorus into p type single crystal Si substrate 1 to form an n type impurity diffusion layer 2 and an anti-reflection film 3 formed of TiOₓ containing phosphorus simultaneously. N type impurity diffusion layer 2 thus formed has a sheet resistance for example of approximately 45 ohms/square.

Then, on a non-light receiving surface (back surface) of p type single crystal Si substrate 1, a silver paste used to form a back surface silver electrode 7 and an aluminum paste used to form an aluminum electrode 8 are printed and subsequently dried. Furthermore, on the light receiving surface (front surface) of p type single crystal Si substrate 1, a silver paste used to form sub grid electrode 5 is printed and subsequently a silver paste used to form main grid electrode 4 is printed. After the silver paste used to form sub grid electrode 5 and the silver paste used to form main grid electrode 4 are printed, they are dried.

The silver paste used to form main grid electrode 4 is different from the silver paste used to form sub grid electrode 5 so that a silver content in the silver paste used to form main grid electrode 4 is lower than a silver content in the silver paste used to form sub grid electrode 5.

The silver paste and the aluminum paste can be printed for example by a screen printing method as follows: a screen having an opening patterned as desired is used to squeegee a paste to form an electrode pattern. Herein, the silver paste is a paste containing silver to serve as a main component of an electrical conducting material, and the aluminum paste is a paste containing aluminum to serve as a main component of an electrical conducting material.

Subsequently, after all electrode patterns are printed, the silver paste and the aluminum paste are fired for example at approximately 800° C. When the silver paste used to form main grid electrode 4 and the silver paste used to form sub grid electrode 5 have a fire-through property, the silver pastes penetrate anti-reflection film 3 and are electrically connected to n type impurity diffusion layer 2.

Furthermore, firing the aluminum paste forms p type single crystal Si substrate 1 with BSF layer 6 that is a p+ layer. Solar cell 11 is thus produced.

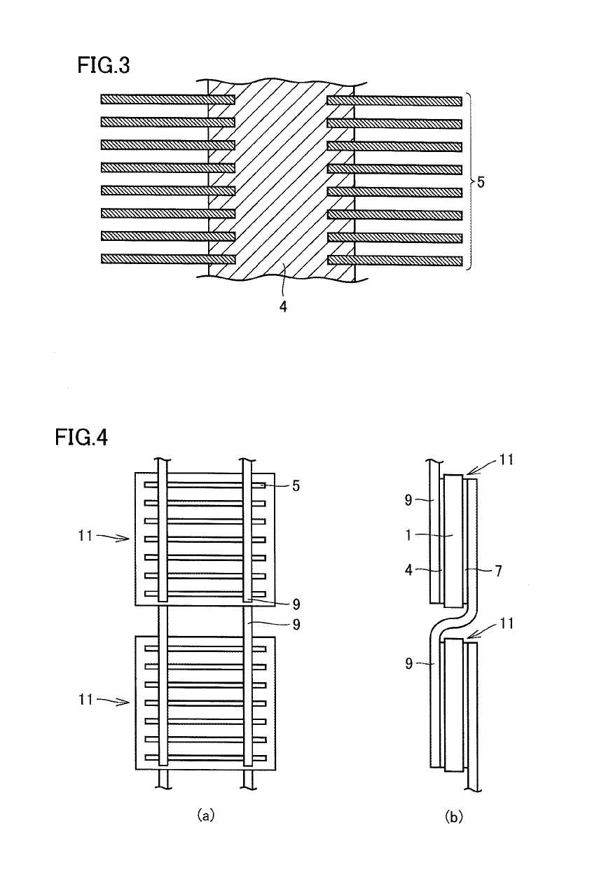

FIG. 3 shows a schematic plan view of joining parts of main grid electrode 4 and sub grid electrode 5. To reduce an amount of the silver paste used to form sub grid electrode 5, sub grid electrode 5 is divided at a portion thereof that overlaps main grid electrode 4.

Herein, sub grid electrode 5 can be formed for example to have a line width of approximately 80 μm and an average thickness of approximately 15 μm. Furthermore, main grid electrode 4 can be formed for example to have a line width of approximately 3 mm and have a center portion with a flat portion having a thickness of approximately 15 μm.

FIG. 4(a) shows a schematic front view of a state of two solar cells 11 connected in series, and FIG. 4(b) shows a schematic side view of the state shown in FIG. 4(a). FIGS. 4(a) and 4(b) show a structure of solar cell 11 in a simplified form.

As shown in FIGS. 4(a) and 4(b), generally, a plurality of solar cells 11 are used in series connection. An interconnector 9 is a connecting member for connecting solar cells 11 in series and connects main grid electrode 4 on the front surface of one solar cell 11 and back surface silver electrode 7 on the back surface of another solar cell 11. Interconnector 9 can be connected via solder for example. Interconnector 9 can have a width for example of approximately 2 mm.

Sub grid electrode 5 and main grid electrode 4 are required to have properties, as will be described hereinafter. Sub grid electrode 5 serves to collect a photocurrent that is generated in solar cell 11 with a minimum loss from an end of sub grid electrode 5 to main grid electrode 4 for a distance of several centimeters, and accordingly, it is required to be small in resistance. As such, reducing a silver content in a silver paste used to form sub grid electrode 5 is not preferable because of increasing resistance.

Main grid electrode 4 and sub grid electrode 5 are formed of fired silver, which is higher in resistivity than pure silver by about one digit. In contrast, interconnector 9 is a solder coated copper wire and can be provided to be comparable in resistivity to pure copper.

Accordingly, main grid electrode 4 does not serve to conduct a current for a long distance; rather, it mainly serves to conduct a current that is collected by sub grid electrode 5 to interconnector 9. The current passes through main grid electrode 4 for a distance equal to or smaller than the width of main grid electrode 4 and hence shorter than a distance that the current travels through sub grid electrode 5, and the current is thus not so much lost by the resistance of main grid electrode 4.

As such, even if resistance of main grid electrode 4 is high due to reduction of a silver content in a silver paste used to form main grid electrode 4, it does not have a significant effect on performance of solar cell 11. The present inventors have noted this and attempted to reduce the silver content in the silver paste used to form main grid electrode 4 to an extent that does not substantially impair performance of solar cell 11.

Furthermore, in the case where a silver paste used to form main grid electrode 4 is different from a silver paste used to form sub grid electrode 5, a low resistance between these electrodes, a high adhesion strength between these electrodes, and reliability for a long term of these electrodes are required.

Furthermore, main grid electrode 4 may receive external force from interconnector 9. Accordingly, main grid electrode 4 is required to have a high adhesive strength to firmly adhere to a surface of solar cell 11 and reliability for a long term so as not to be peeled off from solar cell 11 by the external force. In order to satisfy such conditions, the present inventors have examined various conditions such as an amount of glass frit in a silver paste.

### EXAMPLES

Hereinafter, examples of the present invention will more specifically be described.

In the following examples, sub grid electrode 5 was formed of the same type of silver paste, whereas main grid electrode 4 was formed of a variety of types of silver pastes to examine their properties. Note that the silver paste used to form sub grid electrode 5 serves as a reference silver paste. Note that the silver pastes used in the following examples all have a fire-through property.

### Examples 1-4

In Examples 1-4, the solar cells of Examples 1-4 were fabricated using a silver paste used to form main grid electrode 4, in which a silver content and a glass frit content were varied. Furthermore, in Examples 1-4, the reference silver paste was used in forming sub grid electrode 5. Furthermore, as a reference, a reference solar cell was also fabricated using the reference silver paste in forming both main grid electrode 4 and sub grid electrode 5.

Table 1 shows the properties of the solar cells of Examples 1-4 and the reference solar cell.

TABLE 1

| | Example | Example | Example | Example | Refer- |
|---|---|---|---|---|---|
| | 1 | 2 | 3 | 4 | ence |
| Silver Content (%) | 80 | 78 | 80 | 70 | 83 |
| Glass Frit | 1.6 | 1.6 | 3.6 | 4.1 | 1.5 |
| Content (wt %) | | | | | |
| Ratio of Glass Frit | 2 | 2.1 | 4.5 | 5.8 | 1.8 |
| Content/Silver | | | | | |
| Content (%) | | | | | |
| Silver Content | 96.4 | 94.0 | 96.4 | 84.3 | 100 |
| Ratio (%) | | | | | |
| Maximum Power | 100.4 | 100.1 | 99.7 | 99.9 | 100 |
| Ratio (%) | | | | | |
| Adhesive Strength | A | A | A | A | A |
| Reliability | A | A | A | A | A |

Initially, each of items of Table 1 will be described.

The “Silver Content” and “Glass Frit Content” shown in Table 1 refer to a silver content in a silver paste and a glass frit content in a silver paste, respectively. The “Silver Content” and “Glass Frit Content” shown in Table 1 are represented by wt % (percentage by mass).

The “Ratio of Glass Frit Content/Silver Content” shown in Table 1 refers to a ratio of a glass frit content to a silver content in a silver paste. The “Ratio of Glass Frit Content/Silver Content” is represented by percentage.

The “Silver Content Ratio” shown in Table 1 refers to a ratio of a silver content in each of silver pastes to the silver content in the reference silver content. In Table 1, the “Silver Content Ratio” less than 100% means that usage of silver can be reduced.

The “Maximum Power Ratio” shown in Table 1 refers to a ratio of each of the maximum powers (Pm) of the solar cells of Examples 1-4 to the maximum power (Pm) of the reference solar cell which was fabricated using the reference silver paste in forming both main grid electrode 4 and sub grid electrode 5. In Table 1, the “Maximum Power Ratio” around 100% means that the solar cell has properties equivalent to those of the reference solar cell.

The “Adhesive Strength” shown in Table 1 refers to an adhesive strength of main grid electrode 4. Interconnector 9 having a width of 2.0 mm and a thickness of 0.5 mm and coated with solder was soldered to main grid electrode 4 of each of the solar cells of Examples 1-4 and the reference solar cell and pulled in a direction at an angle of 45 degrees, and a solar cell with interconnector 9 having exhibited a peel strength equal to or larger than 2 N was recognized as a passed solar cell. In the column of “Adhesive Strength” of Table 1, a solar cell that has passed in adhesive strength is represented by “A” and a solar cell that has been rejected in adhesive strength is represented by “B”.

The “Reliability” shown in Table 1 recognizes, of the solar cells of Examples 1-4 and the reference solar cell, a solar cell retaining 98% or more of its maximum power after the solar cell was left in an environment of 85° C. in temperature and 85% in humidity for 500 hours as a passed solar cell. Also in the column of “Reliability” of Table 1, a solar cell that has passed in reliability is represented by “A” and a solar cell that has been rejected in reliability is represented by “B”.

Initially, according to the result of the reference silver paste shown in Table 1, the reference silver paste has passed in both adhesive strength and reliability. It can thus be seen that the reference solar cell at least having main grid electrode 4 and sub grid electrode 5 both formed of the reference silver paste is durable in practical use.

Subsequently, according the results of the solar cells of Examples 1-4, the silver content in the silver paste of each of the solar cells of Examples 1-4 was less than 100%. Accordingly, it can thus be seen that usage of silver can be reduced. Furthermore, the glass frit content in the silver paste used to form main grid electrode 4 of each of the solar cells of Examples 1-4 is larger than that of the reference silver paste (1.5 wt %), which is equal to or larger than 1.6 wt %. Moreover, the ratio of glass frit content/silver content in the silver paste used to form main grid electrode 4 of each of the solar cells of Examples 1-4 is larger than that of the reference silver paste (1.8%), which is equal to or larger than 2%.

On the other hand, the maximum power ratio of each of the solar cells of Examples 1-4 is from 99.7% to 100.4% and thus does not have a substantial difference in performance. Furthermore, each of the solar cells of Examples 1-4 has passed in both adhesive strength and reliability.

Thus it has been found that, by making the silver content in the silver paste used to form main grid electrode 4 lower than the silver content in the silver paste used to form sub grid electrode 5, usage of silver was able to be reduced without substantially impairing performance of each of the solar cells of Examples 1-4.

Furthermore, it has been found that, by making the glass frit content in the silver paste used to form main grid electrode 4 lower than the glass frit content in the silver paste used to form sub grid electrode 5, even if usage of silver in the silver paste was reduced, the solar cells were able to have the performance equivalent to that of the solar cell formed by using the reference silver paste. Thus, in this case, cost reduction was accomplished without substantially impairing performance of each of the solar cells.

Furthermore, it has been found that, by making the ratio of the glass frit content to the silver content in the silver paste used to form main grid electrode 4 larger than the ratio of the glass frit content to the silver content in the silver paste used to form sub grid electrode 5, even if usage of silver in the silver paste was reduced, the solar cells were able to have the performance equivalent to that of the solar cell formed by using the reference silver paste. Thus, in this case, cost reduction was accomplished without substantially impairing performance of each of the solar cells.

### Examples 5-8

In Examples 5-8, the solar cells of Examples 5-8 were fabricated using a silver paste used to form main grid electrode 4, in which a silver content and a softening point of glass frit were varied, and their properties were examined. Furthermore, in Examples 5-8, the reference silver paste was used in forming sub grid electrode 5. Furthermore, as a reference, as set forth above, a reference solar cell was also fabricated using the reference silver paste in forming both main grid electrode 4 and sub grid electrode 5.

Table 2 shows the properties of the solar cells of Examples 5-8 and the reference solar cell.

TABLE 2

| | Example | Example | Example | Example | Refer- |
|---|---|---|---|---|---|
| | 5 | 6 | 7 | 8 | ence |
| Silver Content (%) | 80 | 78 | 80 | 70 | 83 |
| Glass Frit Softening | 550 | 460 | 460 | 560 | 590 |
| Point (° C.) | | | | | |
| Difference in Softening | −40 | −130 | −130 | −30 | 0 |
| Point from Sub Grid (° C.) | | | | | |
| Silver Content Ratio (%) | 96.4 | 94.0 | 96.4 | 84.3 | 100 |
| Maximum Power | 100.4 | 100.1 | 99.7 | 99.9 | 100 |
| Ratio (%) | | | | | |
| Adhesive Strength | A | A | A | A | A |
| Reliability | A | A | A | A | A |

Of the items of Table 2, only those different from those of Table 1 will be described.

The “Glass Frit Softening Point” shown in Table 2 refers to the softening point of the glass frit in each of the silver paste used to form main grid electrode 4 of each of the solar cells of Examples 5-8.

The “Difference in Softening Point from Sub Grid” shown in Table 2 refers to a difference in temperature between the softening point of the glass frit in the silver paste used to form main grid electrode 4 of each of the solar cells of Examples 5-8 and the softening point 590° C. of the glass frit of the reference silver paste used to form sub grid electrode 5.

As shown in Table 2, the silver content in the silver paste used to form main grid electrode 4 of each of the solar cells of Examples 5-8 was less than 100%. Accordingly, it can thus be seen that usage of silver was able to be reduced.

Furthermore, the softening point of the glass frit in the silver paste used to form main grid electrode 4 of each of the solar cells of Examples 5-8 was lower than the softening point (590° C.) of the glass frit of the reference silver paste, which was equal to or lower than 560° C.

On the other hand, the maximum power ratio of each of the solar cells of Examples 5-8 was from 99.7% to 100.4% and thus did not have a substantial difference in performance from the reference solar cell. Furthermore, the solar cells of Examples 5-8 have passed in both adhesive strength and reliability.

From the above results it has been found that, by making the silver content in the silver paste used to form main grid electrode 4 lower than the silver content in the silver paste used to form sub grid electrode 5, usage of silver in the silver paste was able to be reduced.

Furthermore, it has been found that, by making the softening point of the glass frit in the silver paste used to form main grid electrode 4 lower than the softening point of the glass frit in the silver paste used to form sub grid electrode 5, even if usage of silver in the silver paste was reduced, the solar cells were able to have the performance equivalent to that of the solar cell having main grid electrode 4 formed by using the reference silver paste. Thus, in this case, cost reduction was accomplished without substantially impairing performance of each of the solar cells.

### Examples 9-12

In Examples 9-12, the solar cells of Examples 9-12 were fabricated using a silver paste used to form main grid electrode 4, in which a silver content and a BET value (Brunaure Emmett Teller Value) of a silver powder were varied, and their properties were examined. As a silver paste used to form sub grid electrode 5 of each of the solar cells of Examples 9-12, as set forth above, the reference silver paste was used. Furthermore, as a reference, as set forth above, a reference solar cell was also fabricated using the reference silver paste in forming both main grid electrode 4 and sub grid electrode 5.

Table 3 shows the properties of the solar cells of Examples 9-12 and the reference solar cell.

TABLE 3

| | Example | Example | Example | Example | Refer- |
|---|---|---|---|---|---|
| | 9 | 10 | 11 | 12 | ence |
| Silver Content (%) | 80 | 78 | 80 | 70 | 83 |
| Classification of BET | Large | Large | Large | Large | Medium |
| Value of Silver Powder | | | | | |
| Silver Content Ratio (%) | 96.4 | 94.0 | 96.4 | 84.3 | 100 |
| Maximum Power | 100.4 | 100.1 | 99.7 | 99.9 | 100 |
| Ratio (%) | | | | | |
| Adhesive Strength | A | A | A | A | A |
| Reliability | A | A | A | A | A |

Of the items of Table 3, only those different from those of Tables 1 and 2 will be described.

The BET value shown in Table 3 is a value also referred to as a specific surface area, and is a surface area of an object per unit mass. The BET value is used as an indicator of a particle diameter of a silver powder. A larger BET value in Table 3 refers to a smaller particle diameter of a silver powder. Regardless of a shape of a silver powder in a silver paste, it is classified into three classes: a BET value equal to or smaller than 0.25 m²/g is represented by “Small”; a BET value of 0.25-0.50 m²/g is represented by “Medium”; and a BET value equal to or larger than 0.50 m²/g is represented by “Large”, and these representations are shown in Table 3 as a classification of a BET value of a silver powder.

As shown in Table 3, since the silver content ratio in the silver paste used to form main grid electrode 4 of each of the solar cells of Examples 9-12 is less than 100%, usage of silver is able to be reduced. Furthermore, the classification of the BET value of the silver powder of each of the Examples is “Large” and the BET value is larger than the classification “Middle” of the reference silver paste. That is, the particle diameter of the silver powder in the silver paste used to form main grid electrode 4 of each of the solar cells of Examples 9-12 is smaller than the particle diameter of the silver powder used in the reference silver paste.

On the other hand, the maximum power ratio of each of the solar cells of Examples 9-12 was from 99.7% to 100.4% and thus did not have a substantial difference in performance from the reference solar cell. Furthermore, the solar cells of Examples 9-12 have passed in both adhesive strength and reliability.

From the above results it has been found that, by making the silver content in the silver paste used to form main grid electrode 4 lower than the silver content in the silver paste used to form sub grid electrode 5, usage of silver in the silver paste was able to be reduced.

Furthermore, it has been found that, by making the BET value of silver in the silver paste used to form main grid electrode 4 larger than the BET value of silver in the silver paste used to form sub grid electrode 5, even if usage of silver in a silver paste was reduced, the solar cells were able to have the performance of the solar cells equivalent to that of the solar cell formed using the reference silver paste. That is, cost reduction was able to be accomplished without substantially impairing performance of each of the solar cells.

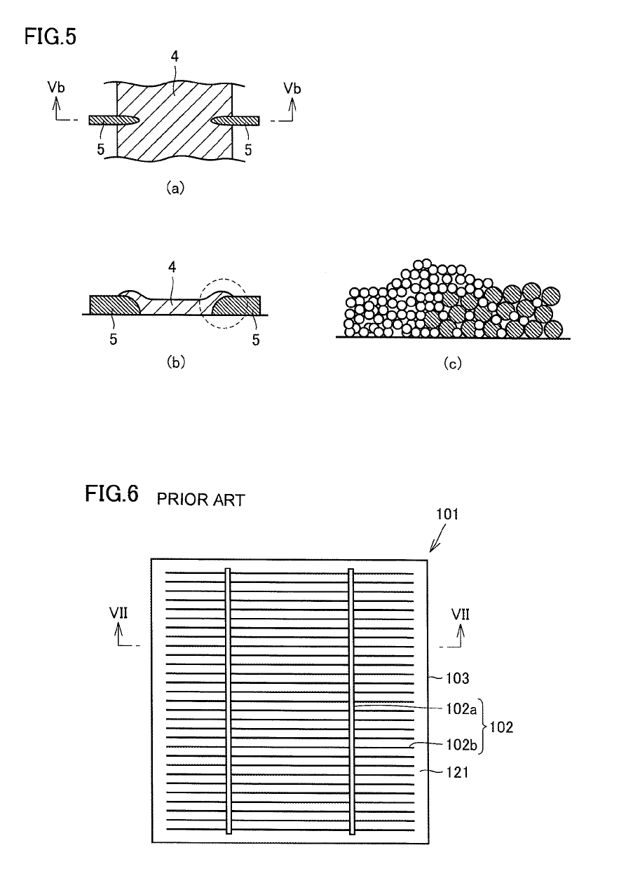

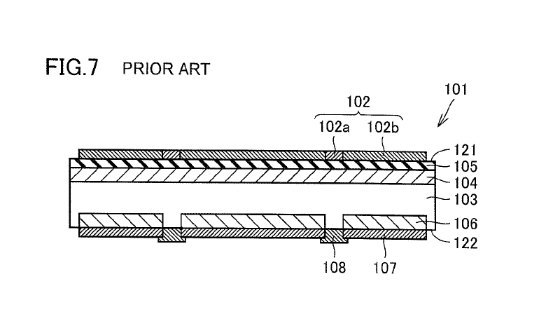

FIGS. 5(a) to 5(c) schematically show a condition of joining parts of main grid electrode 4 and sub grid electrode 5 in Examples 9-12. FIG. 5(a) shows a schematic front view of the joining parts of main grid electrode 4 and sub grid electrode 5, FIG. 5(b) shows a schematic sectional view along a line Vb-Vb shown in FIG. 5(a), and FIG. 5(c) shows a schematic conceptual view for illustrating a condition of silver powders at a portion surrounded by a circle shown in FIG. 5(b). Note that in FIG. 5(c) the white circle represents a silver powder that forms main grid electrode 4 and the hatched circle represents a silver powder that forms sub grid electrode 5.

As shown in FIG. 5(c), since the particle diameter of the silver powder which forms main grid electrode 4 is smaller than the particle diameter of the silver powder which forms sub grid electrode 5, it is believed that the silver powder used to form main grid electrode 4 enters a gap formed in the silver powder used to form sub grid electrode 5, and thus connects main grid electrode 4 and sub grid electrode 5 together with lower resistance and thus allows the electrodes to be in close contact.

### Examples 13-15 and Reference Example 1

In Examples 13-15 and Reference Example 1, thicknesses of main grid electrodes 4 were attempted to be made thinner without substantially impairing performance of each of the solar cells. This is because usage of silver in the silver paste can be further reduced when main grid electrode 4 is formed more thinly.

The reference silver paste was used as a silver paste used to form sub grid electrode 5 of each of the solar cells of Examples 13-15 and Reference Example 1. The reference silver paste was printed by a screen printing method so that a line width of sub grid electrode 5 was approximately 80 μm and an average thickness of sub grid electrode 5 was approximately 15 μm.

Furthermore, the solar cells of Examples 13-15 and Reference Example 1 were fabricated by printing the silver paste used to form main grid electrode 4 of the solar cell of Example 1 by a screen printing method with screens having four different types of thicknesses to form main grid electrodes 4. Each of the thicknesses of main grid electrodes 4 was measured by measuring a flat portion of a center portion of main grid electrode 4 at three points per electrode, which were averaged to provide an average thickness.

Table 4 shows the specification of the screen used to fabricate each of the solar cells of Examples 13-15 and Reference Example 1, and their evaluation results.

TABLE 4

| | Example | | Example | | Example | | Reference | |
|---|---|---|---|---|---|---|---|---|
| | 13 | | 14 | | 15 | | Example 1 | |
| Specification | 165 | mesh | 200 | mesh | 250 | mesh | 280 | mesh |
| of Screen | 45 | μm | 30 | μm | 30 | μm | 30 | μm |

| | | | | |
|---|---|---|---|---|
| | Linear | Linear | Linear | Linear |
| Average Thickness | 10.5 | 6.8 | 5.9 | 4.8 |
| of Main Grid | | | | |
| Electrode (μm) | | | | |
| Maximum Power | 100.1 | 99.7 | 100.2 | 99.6 |
| Ratio (%) | | | | |
| Adhesive Strength | A | A | A | B |
| Reliability | A | A | A | B |

As shown in Table 4, the average thickness of main grid electrode 4 of Example 13 was the largest and that of Reference Example 1 was the smallest. The maximum power ratio of each of the solar cells of Examples 13-15 and Reference Example 1 was from 99.6% to 100.2% and thus did not have a substantial difference in performance from each other. Furthermore, the solar cells of Examples 13-15 have passed in both adhesive strength and reliability, whereas the solar cell of Reference Example 1 has not passed.

The average thickness of each of the solar cells of Examples 13-15 having passed in adhesive strength and reliability was thinner than the average thickness of 15 μm of sub grid electrode 5. As such, in addition to reducing the silver content in the silver paste used to form main grid electrode 4, making the average thickness at the center portion of main grid electrode 4 thinner than the average thickness of sub grid electrode 5 allowed cost reduction by reducing usage of silver in the silver paste without substantially impairing performance of each of the solar cells.

On the other hand, according to the result of Reference Example 1, it has been found that excessively reducing the average thickness at the center portion of main grid electrode 4 impairs adhesive strength and reliability. According to the above results, there exists criticality between the average thickness of 5.9 μm at the center portion of main grid electrode 4 of the solar cell of Example 15 and the average thickness of 4.8 μm at the center portion of main grid electrode 4 of the solar cell of Reference Example 1, and accordingly, desirably, the average thickness of the center portion of main grid electrode 4 is equal to or larger than 5.4 μm and more desirably equal to or larger than 5.9 μm.

In Examples 13-15 and Reference Example 1, the thickness of main grid electrode 4 has been changed by varying the specification of the screen. However, the thickness of main grid electrode 4 can also be changed by varying a viscosity of a silver paste.

Thus the present invention can produce a solar cell having electrical properties, adhesive strength and reliability equivalent to those of a current solar cell inexpensively.

While the present invention has been described in an embodiment and examples, the embodiment and each example are also originally intended to be combined together in configuration, as appropriate.

It should be understood that the embodiment and examples disclosed herein have been described for the purpose of illustration only and in a non-restrictive manner in any respect. The scope of the present invention is defined by the terms of the claims, rather than the description above, and is intended to include any modifications within the meaning and scope equivalent to the terms of the claims.

### INDUSTRIAL APPLICABILITY

The present invention is widely applicable to methods for producing solar cells each having a main grid electrode and a sub grid electrode formed of different silver pastes, respectively, the solar cells, and solar cell modules that employ the solar cells, in general.

### REFERENCE SIGNS LIST

1: p type single crystal Si substrate; 2: n type impurity diffusion layer; 3: anti-reflection film; 4: main grid electrode; 5: sub grid electrode; 6: BSF layer; 7: back surface silver electrode; 8: aluminum electrode; 9: interconnector; 11: solar cell; 101: solar cell; 102: electrode unit; 102a: main grid; 102b: sub grid; 103: silicon substrate; 104: n type impurity diffusion layer; 105: anti-reflection film; 106: BSF layer; 107: aluminum electrode; 108: silver electrode; 121: light receiving surface; 122: back surface.

1. A solar cell comprising:
a substrate;
a sub grid electrode and a main grid electrode directly contacting the substrate;
wherein the main grid electrode and the sub grid electrode comprise silver particles, and
wherein a particle size of the silver particles comprised in the main grid electrode is smaller than a particle size of the silver particles comprised in the sub grid electrode.

2. The solar cell of claim 1, wherein an average thickness in a center portion of the main grid electrode is thinner than an average thickness in a center portion of the sub grid electrode.

3. The solar cell of claim 2, wherein the average thickness in the center portion of the main grid electrode is thicker than 4.8 μm.

4. The solar cell of claim 1, wherein the silver particles comprised in the main grid electrode exist among the silver particles comprised in the sub grid electrode at joining parts of the main grid electrode and the sub grid electrode.

5. The solar cell of claim 1, wherein the sub grid electrode is divided by the main grid electrode.

6. The solar cell of claim 1, wherein a glass frit content in a silver paste used to form the main grid electrode is higher than a glass frit content in a silver paste used to form the sub grid electrode.

7. The solar cell of claim 1, wherein a ratio of a glass frit content to a silver content in a silver paste used to form the main grid electrode is higher than a ratio of a glass frit content to a silver content in a silver paste used to form the sub grid electrode.

8. The solar cell of claim 1, wherein a softening point of glass frit in a silver paste used to form the main grid electrode is lower than a softening point of a glass frit in a silver paste used to form the sub grid electrode.

9. The solar cell of claim 1, wherein a Brunaure Emmett Teller (BET) value of silver in a silver paste used to form the main grid electrode is larger than a BET value of silver in a silver paste used to form the sub grid electrode.

10. A device comprising:
at least two solar cells of claim 1;
an electrode on a back surface of the substrate opposite to the surface directly contacting with the main electrode; and
an interconnector connecting the main grid electrode on the surface of one solar cell and the electrode on the back surface of another solar cell.

11. A method for producing a solar cell comprising:
forming a main grid electrode and a sub grid electrode directly on a surface of a substrate;
wherein a particular size of the silver particles comprised in the main grid electrode is smaller than a particle size of the silver particles comprised in the sub grid electrode.

12. The method of claim 11, wherein the solar cell comprises an anti-reflection film on the surface of the substrate.

13. The method of claim 11, wherein the step of forming the main grid electrode and the sub grid electrode directly on the surface of the substrate comprises penetrating the silver particles through the anti-reflection film.

14. The method of claim 11, further comprising forming a thickness of the main grid electrode to be thinner than a thickness of the sub grid electrode.

15. The method of claim 11, further comprising forming the sub grid electrode using a silver paste having a glass frit content which is higher than a glass frit content in a silver paste used to form the sub grid electrode.

16. The method of claim 11, further comprising forming the main grid electrode using a silver paste having a ratio of a glass frit content to a silver content which is higher than a ratio of a glass frit content to a silver content in the silver paste used to form the sub grid electrode.

17. The method of claim 11, further comprising forming the main grid electrode using a silver paste comprising a glass frit having a softening point which is lower than a softening point of a glass frit in a silver paste used to form the sub grid electrode.

18. The method of claim 11, further comprising forming the main grid electrode using a silver paste having a Brunaure Emmett Teller (BET) value which is larger than a BET value of a silver paste used to form the sub grid electrode.
